(19) United States
(12) Patent Application Publication
(10) Pub. No.: US 2022/0146122 A1
(43) Pub. Date: May 12, 2022

(54) PASSIVE HEAT EXCHANGER WITH SINGLE MICROCHANNEL COIL

(71) Applicant: Dantherm Cooling, Inc., Spartanburg, SC (US)

(72) Inventors: Allen Charles Stegall, Spartanburg, SC (US); Jodi Elizabeth Humphries, Spartanburg, SC (US); Charles Richard Schmidt, Jr., Spartanburg, SC (US); Troy F. Berg, Spartanburg, SC (US); Osbaldi Boekhoudt, Spartanburg, SC (US)

(73) Assignee: Dantherm Cooling, Inc., Spartanburg, SC (US)

(21) Appl. No.: 17/434,120

(22) PCT Filed: Feb. 27, 2020
(86) PCT No.: PCT/US2020/020128

§ 371 Date: Aug. 26, 2021

Related U.S. Application Data
(60) Provisional application No. 62/811,248, filed on Feb. 27, 2019.

(51) Int. Cl. F24F 1/14; F24F 1/38; F24F 11/871; F25B 39/02; F25B 39/04; F28D 1/02; F28D 1/04; F28D 1/053; F28D 15/02; F28F 1/02; H05K 7/20; F25B 23/00; F28F 9/02

(52) U.S. Cl. CPC F24F 1/14; F28D 2021/007; F24F 11/871; F25B 39/02; F25B 39/04; F28D 1/024; F28D 1/0443; F28D 1/05391; F28D 15/0266; F28D 15/0275; F28F 1/022; H05K 7/20609; H05K 7/207; F25B 23/006; F28F 9/0212; F28D 2015/0216; F24F 1/38

(57) ABSTRACT

The present disclosure provides materials and methods related to passive cooling systems. In particular, the present disclosure provides a condensorator heat exchanger with a single microchannel coil that integrates the evaporator and condenser into one assembly. The passive heat exchanger systems of the present disclosure provide enhanced cooling capacity and airflow in environments ranging from outdoor electronic enclosures to commercial and residential buildings.

### CROSS REFERENCE TO RELATED APPLICATIONS

This application claims priority to and the benefit of U.S. Provisional Patent Application No. 62/811,248 filed Feb. 27, 2019, which is incorporated herein by reference in its entirety for all purposes.

### FIELD

The present disclosure provides systems, materials, devices, and methods related to passive cooling systems. In particular, the present disclosure provides a heat exchanger having a single coil that integrates an evaporator and condenser into one assembly. The passive heat exchanger systems of the present disclosure provide enhanced cooling capacity and airflow in environments ranging from outdoor electronic enclosures to commercial and residential buildings.

### BACKGROUND

To address and alleviate the challenges and inefficiencies that arise as a result of heat generated naturally from the sun or through the use of electronic and industrial equipment, two main categories of cooling systems are generally recognized: active and passive cooling systems. The advantages of passive cooling technologies include energy efficiency and lower financial cost, making these systems particularly useful for the thermal management of both buildings and electronic products. Passive cooling achieves high levels of natural convection and heat dissipation by utilizing a heat sink to maximize the radiation and convection heat transfer modes. This can lead to proper cooling of electronic products and thermal comfort in homes or office buildings by keeping them under the maximum allowed operating temperature.

Active cooling, on the other hand, refers to cooling technologies that rely on an external device to enhance heat transfer. Through active cooling technologies, the rate of fluid flow increases during convection, which dramatically increases the rate of heat removal. Active cooling solutions include forced air through a fan or blower, forced liquid, and thermoelectric coolers (TECs), which can be used to optimize thermal management on all levels. Fans are used when natural convection is insufficient to remove heat. They are commonly integrated into electronics, such as computer cases, or are attached to CPUs, hard drives or chipsets to maintain thermal conditions and reduce failure risk. The main disadvantage of active thermal management is that it requires the use of electricity (e.g., a passive solution can use some electricity, such as fans, whereas active thermal management generally uses a pump or compressor in addition to the fans) and therefore results in higher costs, compared to passive cooling.

For electronic enclosures, which generally include systems designed to house and protect sensitive and valuable computer and electronic equipment (e.g., equipment used by the Telecom, Industrial, Natural Resources Refining, Federal and Municipal Government or other industries), it is necessary for the internal area of the enclosure to be climate controlled (e.g., regulated temperature and humidity) and to be protected from the intrusion of dust and debris from the outside environment. Often times, to control the environment of the electronic enclosure, a climate control unit (CCU) is used. A CCU is designed to reduce intrusion of outdoor contaminates like dust, water, salt etc. while also controlling the temperature of the equipment being protected. Examples of active cooling CCUs include air conditioners, heat pumps, and water source geothermal HVAC systems. Examples of passive cooling CCUs include air to air heat exchangers, heat pipes, and thermosiphons. Passive cooling typically offers lower electrical consumption, with less heat removal capacity in comparison to an active cooling unit.

With increasing heat load requirements in electronic enclosures, as well as commercial and residential buildings, currently available passive cooling technology has not been widely implemented despite its advantages. Although active cooling technologies provide increased capacities, higher costs coupled with increased energy consumption creates operational burdens. Thus, there is a demand for a CCU that operates with low energy consumption while still offering higher heat removal that will effectively bridge the gap between passive and active cooling technologies.

### SUMMARY

Embodiments of the present disclosure include a single coil passive heat exchanger device. In accordance with these embodiments, the coil comprises a plurality of channels and a working fluid in a saturated state. In some embodiments, the coil is comprised of aluminum or an aluminum alloy.

In some embodiments, the device further comprises a divider plate, which creates a substantially air-tight seal that divides the coil into an upper coil portion and a lower coil portion. In some embodiments, the upper coil comprises working fluid in a substantially gaseous state, and the lower coil comprises working fluid in a substantially liquid state. In some embodiments, the divider plate is positioned such that the upper and lower coil portions are substantially equivalent in length. In some embodiments, the divider plate is positioned such that the upper and lower coil portions are from about 1% to about 99% of the total length of the coil. In some embodiments, the divider plate is welded, brazed, or fitted mechanically with a sealant compound into a stationary position. In some embodiments, the divider plate is vertically adjustable or expandable along the length of the coil.

In some embodiments, the device further comprises a header and a footer positioned at each terminal end of the coil. In some embodiments, the header and footer are sealed at each terminal end of the coil to create sealed header and footer compartments, and the working fluid can move freely within both the header and footer compartments and within the plurality of channels. In some embodiments, the header comprises working fluid in a substantially gaseous state, and the footer comprises working fluid in a substantially liquid state. In some embodiments, the header further comprises one or more charge ports through which working fluid is added to the device. In some embodiments, the header and footer are divided into a plurality of sealed header and footer compartments that create a plurality of coil circuits, with each header and footer compartment comprising at least one channel and at least one charge port.

In some embodiments, the plurality of channels each comprise a plurality of microchannels. In some embodiments, the plurality of microchannels each comprise a plurality of fins extending from the plurality of microchannels that increase the surface area for heat transfer. In some embodiments, the plurality of fins extends from one or both lateral sides of a microchannel. In some embodiments, the plurality of fins is bonded to the plurality of microchannels. In some embodiments, the plurality of fins is formed from the same material as that of the plurality of microchannels.

Embodiments of the present disclosure also include a passive cooling system comprising the single coil passive heat exchanger device described above, at least one fan, and a housing unit.

In some embodiments, the system comprises one or more external fan(s) and one or more internal fan(s). In some embodiments, the external fan or fans is positioned at a bottom portion of the housing unit in a sealed compartment coupled to the divider plate. In some embodiments, the external fan or fans draws external air into the sealed compartment and upward towards the upper coil comprising working fluid in a substantially gaseous state sufficient to cause condensation of the gaseous working fluid. In some embodiments, the internal fan or fans is positioned in a top portion of the housing unit in a sealed compartment coupled to the divider plate. In some embodiments, the internal fan or fans draws internal air from an enclosure-of-interest into the sealed compartment and downward towards the lower coil comprising working fluid in a substantially liquid state sufficient to cause evaporation of the liquid working fluid. In some embodiments, the angle of the coil is from 1 to 90 degrees with reference to the ground.

In some embodiments, the one or more external fan(s) are positioned in the top portion of the housing unit in a sealed compartment coupled to the divider plate. In some embodiments, the one or more external fan(s) draw external air into the sealed compartment and against the upper coil comprising working fluid in a substantially gaseous state sufficient to cause condensation of the gaseous working fluid. In some embodiments, the one or more internal fan(s) are positioned in the bottom portion of the housing unit in a sealed compartment coupled to the divider plate. In some embodiments, the one or more internal fan(s) draw internal air from an enclosure-of-interest into the sealed compartment and against the lower coil comprising working fluid in a substantially liquid state sufficient to cause evaporation of the liquid working fluid. In some embodiments, the angle of the coil is from 1 to 90 degrees with reference to the ground.

In some embodiments, the system is mounted to an enclosure-of-interest, and wherein the enclosure-of-interest houses electrical or computer equipment. In some embodiments, the enclosure-of-interest houses one or more of batteries, drives, relays, switches, transformers, electrical, computer, or any combinations thereof, which generate thermal load. In some embodiments, the system is mounted to an enclosure-of-interest, and wherein the enclosure-of-interest is a commercial or residential building, or an air management system housed therein. In some embodiments, the speed of the external and internal fan or fans are adjustable based on one or more system parameters. In some embodiments, the one or more system parameters comprise at least one of external air temperature, internal air temperature, internal humidity, internal airflow, external humidity, time of day, day of year, external wind speed, external precipitation, static pressure of the working fluid, and functional capacity of the system.

In some embodiments, the one or more system parameters are measured using at least one sensor. In some embodiments, data provided by the at least one sensor is transferable to a computing device that is read by a user. In some embodiments, the divider plate is vertically adjustable or expandable along the length of the coil, wherein adjusting the position of the divider plate on the coil alters the configurations of the sealed compartment containing the one or more internal fan(s) and the sealed compartment containing the one or more external fan(s). In some embodiments, the position of the divider plate is adjustable based on information from the one or more system parameters read by the at least one sensor.

Embodiments of the present disclosure also include methods of operating a single coil passive heat exchanger device/system based on one or more system parameters. In some embodiments, the methods include sending power to the controls of the system when the internal and/or external temperature is more than or less than a temperature set point or threshold. In some embodiments, if the temperature does not reach a predetermined set point, power to the internal or external fan can be removed. In other embodiments, if the temperature reaches a predetermined set point, power to the external and/or internal fan can be provided, and can also be controlled based on, for example, continual temperature measurements.

### BRIEF DESCRIPTION OF THE DRAWINGS

FIGS. 1A and 1B include representative perspective (FIG. 1A) and exploded view, including a cutaway view of the header for viewing the internal region, (FIG. 1B) of a single coil passive heat exchanger, according to one embodiment of the present disclosure.

FIGS. 2A-2F include representative cutaway views of various configurations of the header of the heat exchangers of the present disclosure, including a cutaway view of the header for viewing the internal region. FIG. 2A provides a perspective view of the terminal end of the plurality of channels contained within the header compartment, while FIG. 2B provides a perspective view of the plurality of microchannels within each channel. FIGS. 2C and 2D provide perspective views of channels extending into the header compartment at different depths, including a cutaway view of the header for viewing the internal region. FIG. 2E illustrates the flow of the working fluid among the channels within the header compartment, as well as a charge port. FIG. 2F provides a representative schematic of the single coil assembly design in which the working fluid is substantially in a gaseous state in the upper coil portion (e.g., condenser) and substantially liquid state in the lower coil portion (e.g., evaporator), with reference to the divider plate.

FIGS. 3A and 3B include representative cutaway views a single coil passive heat exchanger with a single header compartment and charge port (FIG. 3A), and multiple header compartments with multiple charge ports (FIG. 3B) within the header (e.g., multiple coil circuits).

FIG. 4 includes a representative schematic of the flow of the working fluid (small arrows), the internal airflow within the enclosure-of-interest circulating across the lower coil portion (large arrow indicating cabinet airflow), and the external airflow from outside of the system flowing across the upper coil portion (large arrow indicating ambient airflow). Due to the presence of the divider plate, the two airflow paths do not cross or mix, which facilitates the removal of heat from the enclosure-of-interest and prevents contaminants from the outside environment from mixing with internal air.

FIGS. 5A-5F include representative views of a single coil passive heat exchanger with multiple header compartments and fins extending from the microchannels. FIG. 5A provides a perspective view (divider plate not shown) of the device, while FIG. 5B provides an exploded view. FIGS. 5C-5E provide magnified views of the plurality of microchannels within individual coil circuits and the fins extending from both lateral sides of the microchannels. FIG. 5F is a representative embodiment having fins orientated same direction and no overlap.

FIGS. 6A-6E include representative cutaway views of a system comprising a single coil passive heat exchanger of the present disclosure. FIGS. 6A and 6B provide different cutaway perspective views of the single coil passive heat exchanger positioned at an angled configuration within a housing unit and mounted to an enclosure-of-interest (e.g., a cabinet containing electrical equipment). An external and internal fan are also shown (single fan design). FIGS. 6C-6E provide views of the system dismounted from the enclosure-of-interest and with the heat exchanger device removed. FIG. 6C provides a cutaway frontal view of the system, FIG. 6D provides a cutaway lateral view of the system, and FIG. 6E provides a cutaway perspective view of the system.

FIGS. 7A-7E include representative cutaway views of a system comprising a single coil passive heat exchanger of the present disclosure, wherein the single coil passive heat exchanger is positioned at an alternative angled configuration compared to FIGS. 6A-6E. FIGS. 7A and 7B provide different cutaway perspective views of the single coil passive heat exchanger positioned at an angle within a housing unit and mounted to an enclosure-of-interest (e.g., a cabinet containing electrical equipment). Two external and two internal fans are also shown (dual fan design). FIGS. 7C-7E provide views of the system dismounted from the enclosure-of-interest and with the heat exchanger device removed. FIG. 7C provides a cutaway frontal view of the system, FIG. 7D provides a cutaway lateral view of the system, and FIG. 7E provides a cutaway perspective view of the system.

FIG. 8 includes a representative cutaway perspective view of a system comprising the single coil passive heat exchanger of the present disclosure mounted to an enclosure-of-interest. Dashed arrows represent ambient airflow external to the enclosure-of-interest, with the darker arrows representing warmer air and lighter arrows representing cooler air. The small arrows represent airflow within the enclosure-of-interest, with the darker arrows representing warmer air and lighter arrows representing cooler air.

FIGS. 9A-9C include representative schematics of airflow within a system comprising the single coil passive heat exchanger of the present disclosure designed for residential and commercial enclosures (e.g., as an air exchange component). In FIG. 9A, arrows at the top and to the left of the heat exchanger (flowing left to right) represent cooler ambient airflow moving across the upper coil portion (e.g., condenser), while the arrows at the bottom and to the right of the heat exchanger (flowing right to left) represent warmer airflow from the enclosure moving across the lower coil portion (e.g., evaporator). FIGS. 9B and 9C include representative schematics of a system comprising the single coil passive heat exchanger of the present disclosure integrated into the ductwork of a residential or commercial building, which includes dampers to reverse the direction of airflow.

FIG. 10 is a representative flowchart of command/control operations for the single coil passive heat exchanger devices/systems of the present disclosure, including commands for operating both the internal and external fans in response to various system parameters.

### DETAILED DESCRIPTION

The present disclosure provides systems, devices, materials and methods related to passive cooling systems. In particular, the present disclosure provides a single assembly system that acts as both condenser and evaporator (a “condensorator”). The single assembly systems described herein include a heat exchanger comprising a single microchannel coil that integrates the evaporator and condenser into one assembly. The passive heat exchanger systems of the present disclosure provide enhanced cooling capacity and airflow in environments ranging from outdoor electronic enclosures to commercial and residential buildings or in any environment of application where heat exchange is desired or useful.

Embodiments of the present disclosure generally include a single assembly heat exchanger having a single microchannel coil assembly with shared fluid passages and a divider to create separate air paths that are exposed to regions of the assembly. In some embodiments, fans are used to circulate air through the separated air paths (e.g., internal vs. external airflow paths). Water (or other fluid) cooling can be substituted for one or both paths. In accordance with these embodiments, the single assembly design improves the efficiency of a passive cooling system by increasing the heat removal capacity. In some embodiments, the assembly includes multiple channels or microchannels to increase the surface area for heat transfer. The systems of the present disclosure address many of the limitations associated with currently available technologies found in climate-controlled units; for example, typical thermosiphon systems utilize two coils (condenser and evaporator) and typical heat pipe systems utilize a single pipe/path.

In some embodiments, the single assembly heat exchanger systems of the present disclosure are fitted with a divider plate. A purpose of the divider plate is to separate the internal and external air flow paths to protect the contents of the internal environment. The divider plate can be welded or brazed in place during the assembly process. By separating the paths, contamination of the internal environment with water, dirt, dust, and debris is prevented. By contrast, a looped thermosiphon uses a seal (cable gland) on the round pipe connecting the two coils and is installed after the coils are assembled. Additionally, embodiments of the present disclosure provide increased heat removal by use of a working fluid (e.g., an environmentally friendly refrigerant). By harnessing the thermal transfer of the working fluid inside the coil, cooling capacity is significantly greater than other currently available passive cooling technologies.

Embodiments of the single assembly heat exchanger systems of the present disclosure include, but are not limited to, reduced manufacturing costs with a single coil vs. two or more coils; a divider welded/brazed into place during an initial manufacturing step vs. adding it in a separate step; improved sealing between the external and internal airflow paths; and increased performance by eliminating the restrictions between a condenser and an evaporator.

Section headings as used in this section and the entire disclosure herein are merely for organizational purposes and are not intended to be limiting.

### 1. Definitions

Unless otherwise defined, all technical and scientific terms used herein have the same meaning as commonly understood by one of ordinary skill in the art. In case of conflict, the present document, including definitions, will control. Preferred methods and materials are described below, although methods and materials similar or equivalent to those described herein can be used in practice or testing of the present disclosure. All publications, patent applications, patents and other references mentioned herein are incorporated by reference in their entirety. The materials, methods, and examples disclosed herein are illustrative only and not intended to be limiting.

The terms “comprise(s),” “include(s),” “having,” “has,” “can,” “contain(s),” and variants thereof, as used herein, are intended to be open-ended transitional phrases, terms, or words that do not preclude the possibility of additional acts or structures. The singular forms “a,” “and” and “the” include plural references unless the context clearly dictates otherwise. The present disclosure also contemplates other embodiments “comprising,” “consisting of” and “consisting essentially of,” the embodiments or elements presented herein, whether explicitly set forth or not.

For the recitation of numeric ranges herein, each intervening number there between with the same degree of precision is explicitly contemplated. For example, for the range of 6-9, the numbers 7 and 8 are contemplated in addition to 6 and 9, and for the range 6.0-7.0, the number 6.0, 6.1, 6.2, 6.3, 6.4, 6.5, 6.6, 6.7, 6.8, 6.9, and 7.0 are explicitly contemplated.

For the recitation of numeric ranges herein, each intervening number there between with the same degree of precision is explicitly contemplated. For example, for the range of 6-9, the numbers 7 and 8 are contemplated in addition to 6 and 9, and for the range 6.0-7.0, the number 6.0, 6.1, 6.2, 6.3, 6.4, 6.5, 6.6, 6.7, 6.8, 6.9, and 7.0 are explicitly contemplated.

As used herein, the terms “processor” and “central processing unit” or “CPU” are used interchangeably and refer to a device that is able to read a program from a computer memory (e.g., ROM or other computer memory) and perform a set of steps according to the program.

As used herein, the terms “computer memory” and “computer memory device” refer to any storage media readable by a computer processor. Examples of computer memory include, but are not limited to, RAM, ROM, computer chips, digital video discs (DVD), compact discs (CDs), hard disk drives (HDD), optical discs, and magnetic tape. In certain embodiments, the computer memory and computer processor are part of a non-transitory computer (e.g., in the control unit). In certain embodiments, non-transitory computer readable media is employed, where non-transitory computer-readable media comprises all computer-readable media with the sole exception being a transitory, propagating signal.

As used herein, the term “computer readable medium” refers to any device or system for storing and providing information (e.g., data and instructions) to a computer processor. Examples of computer readable media include, but are not limited to, DVDs, CDs, hard disk drives, magnetic tape and servers for streaming media over networks, whether local or distant (e.g., cloud-based).

As used herein, the term “in electronic communication” refers to electrical devices (e.g., computers, processors, etc.) that are configured to communicate with one another through direct or indirect signaling. Likewise, a computer configured to transmit (e.g., through cables, wires, infrared signals, telephone lines, airwaves, etc.) information to another computer or device, is in electronic communication with the other computer or device.

As used herein, the term “transmitting” refers to the movement of information (e.g., data) from one location to another (e.g., from one device to another) using any suitable means.

Unless otherwise defined herein, scientific and technical terms used in connection with the present disclosure shall have the meanings that are commonly understood by those of ordinary skill in the art. For example, any nomenclatures used in connection with, and techniques of, cell and tissue culture, molecular biology, immunology, microbiology, genetics and protein and nucleic acid chemistry and hybridization described herein are those that are well known and commonly used in the art. The meaning and scope of the terms should be clear; in the event, however of any latent ambiguity, definitions provided herein take precedent over any dictionary or extrinsic definition. Further, unless otherwise required by context, singular terms shall include pluralities and plural terms shall include the singular.

### 2. Heat Exchanger

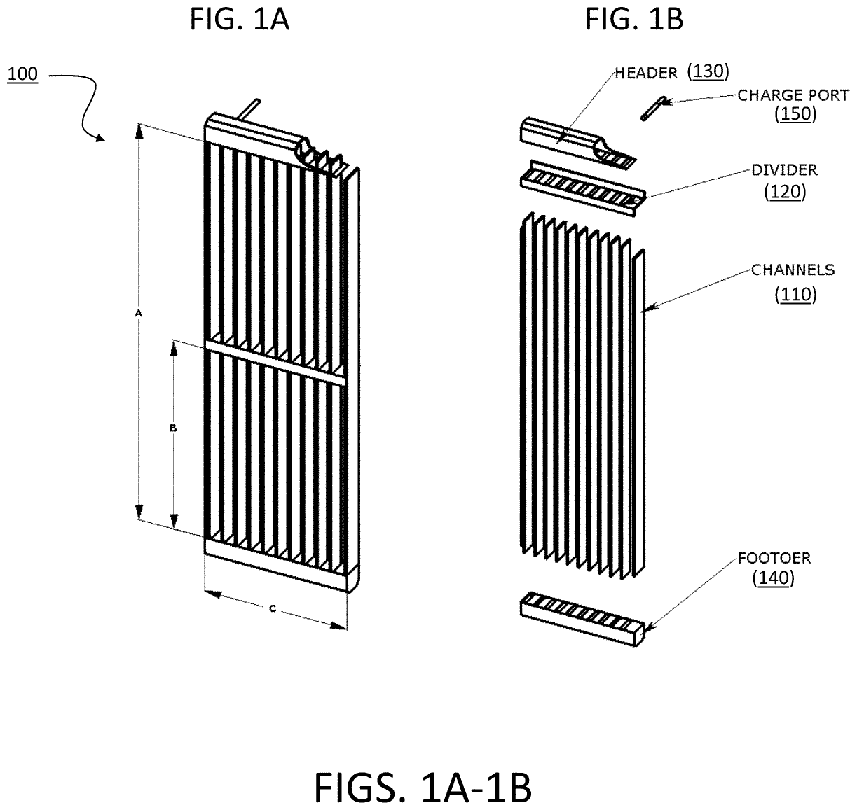

Embodiments of the present disclosure include a single coil passive heat exchanger device. Referring to FIGS. 1A and 1B, heat exchanger devices of the present disclosure generally comprise a single coil assembly such that the coil typically referred to as a condenser and the coil typically referred to as an evaporator are not separate coils connected by piping (e.g., as with looped thermosiphon designs), but are a single continuous configuration (e.g., a “condensorator”), as shown in FIG. 1A (100). FIG. 1B further provides that the single coil heat exchanger device 100 includes a plurality of channels 110 that contain a working fluid (e.g., refrigerant) inside the coil. The coil is divided into upper and lower portions using a divider plate 120. The divider plate facilitates the separation of an external airflow path across the upper portion of the coil from an internal airflow path across the lower portion of the coil. In this manner, the single coil heat exchanger devices of the present disclosure provide enhanced cooling of an enclosure-of-interest, while preventing contamination of the internal environment of the enclosure-of-interest with dust, debris, dirt, salt, precipitation, and the like, from the environment outside of the enclosure-of-interest.

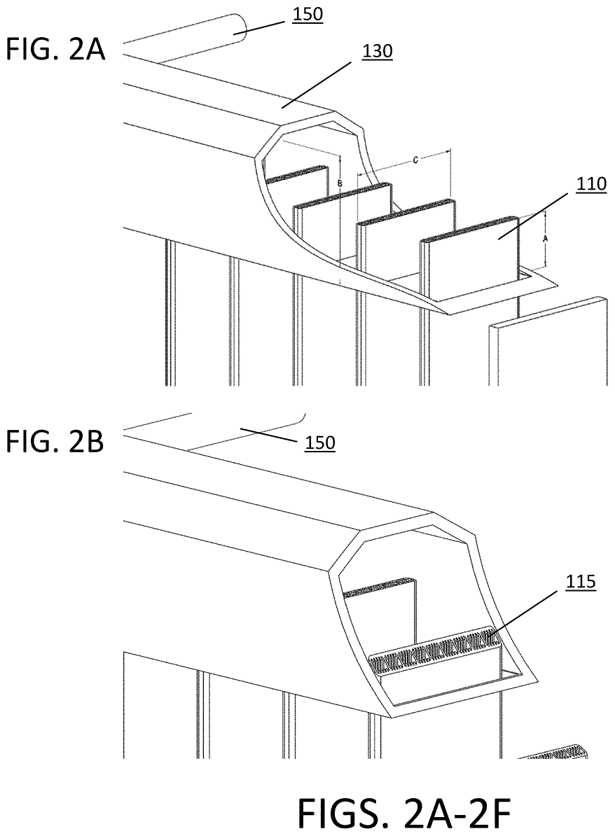

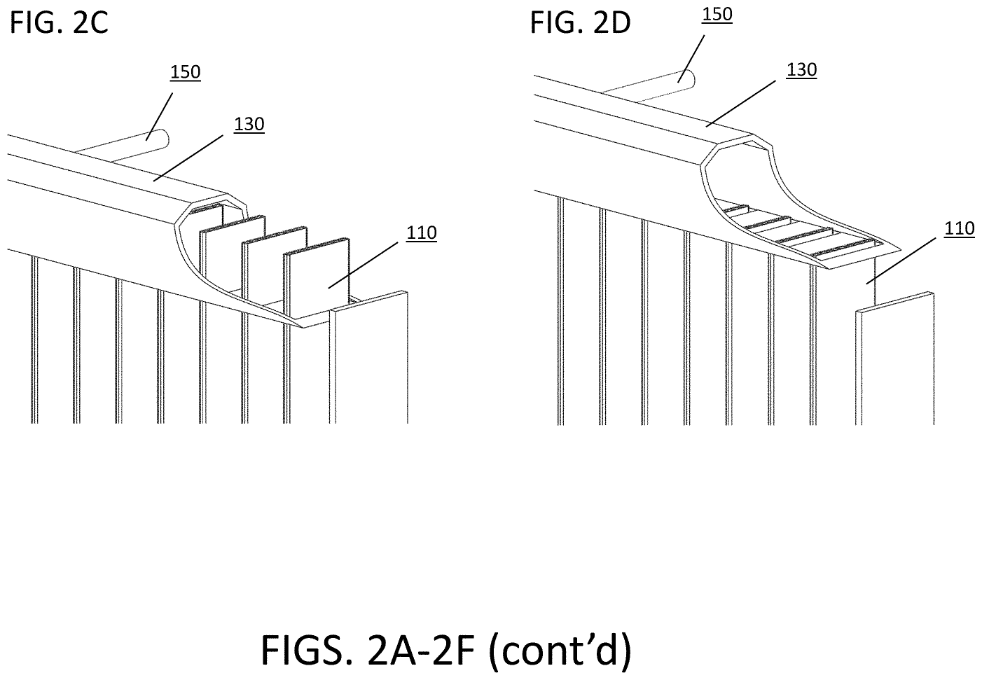

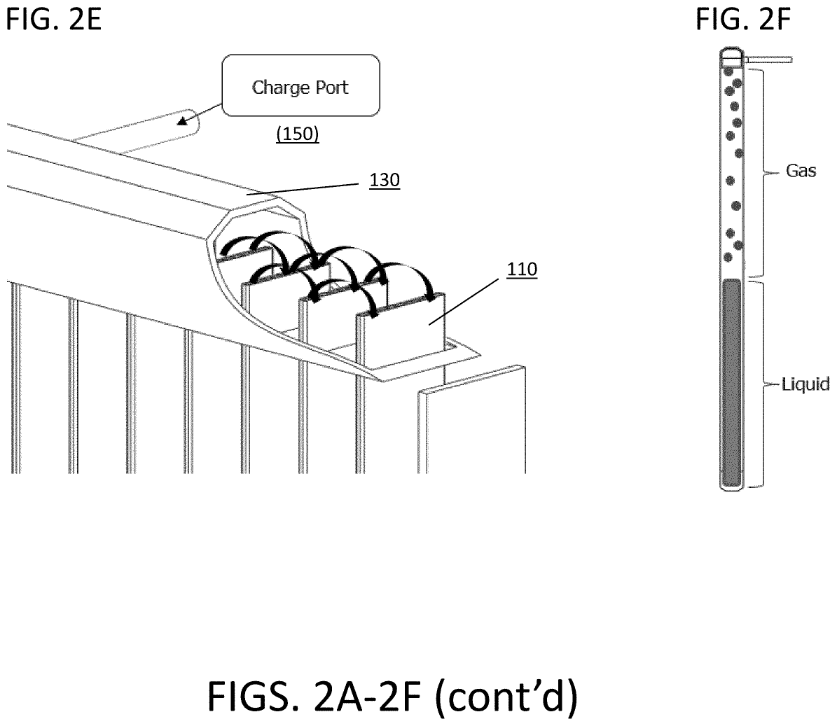

The plurality of channels 110 increase the surface area for heat transfer. In some embodiments, the heat exchanger devices of the present disclosure include 2 or more channels, including, but not limited to, 3, 4, 5, 6, 7, 8, 9, 10, 12, 14, 16, 18, 20, 30, 40, 50, 60, 70, 80, 90, 100 or more separate channels within the coil. The number of channels can be determined based on various factors, such as system parameters, the working fluid, the size and spatial limitations of the enclosure-of-interest, the heat load of the enclosure-of-interest, the external environment, and the like. In some embodiments, the channels within the coil include a plurality of microchannels 115, as illustrated, for example, in FIG. 2B. In some embodiments, the heat exchanger devices of the present disclosure include 2 or more microchannels 115, including, but not limited to, 3, 4, 5, 6, 7, 8, 9, 10, 12, 14, 16, 18, 20, 30, 40, 50, 60, 70, 80, 90, 100 or more separate microchannels 115 within a single channel 110 within coil. As with the channels, the number of microchannels can be determined based on various factors, such as system parameters, the working fluid, the size and spatial limitations of the enclosure-of-interest, the heat load of the enclosure-of-interest, the external environment, and the like.

The configurations of the channels 110 and microchannels 115 (e.g., size, shape, depth) can also vary depending on these and other factors. Generally, the channels and microchannels are configured to maximize heat transfer within a given area; therefore, any configuration that contributes to greater heat transfer can be used. In some embodiments, the channels 110 and microchannels 115 are symmetrically configured and/or are of uniform shape and size with respect to the other channels 110 and microchannels in the heat exchanger. In other embodiments, the channels 110 and microchannels 115 are asymmetrically configured and/or are of variable shape and size with respect to the other channels 110 and microchannels in the heat exchanger.

In some embodiments, the configurations of the channels and microchannels are a result of the material and methods used to manufacture the coil itself. For example, the channels 110 and microchannels 115 can be formed using an extrusion process, which is a process by which material is pushed or pulled through a cast or die of a specific cross-sectional pattern to create a uniform profile. Any suitable material can be used, including but not limited to aluminum, titanium, copper, steel, or any alloys thereof, as well as plastics, PVC pipe, rubber, carbon fiber, or any other material with suitable heat transfer characteristics.

In some embodiments, the divider plate 120 facilitates the separation of an external airflow path across the upper portion of the coil from an internal airflow path across the lower portion of the coil to prevent contamination of the internal environment of the enclosure-of-interest. The divider plate 120 creates a substantially air-tight seal that divides the coil into an upper coil portion and a lower coil portion, as shown in FIG. 1A. Generally, the upper coil portion above the divider plate 120 contains working fluid in a substantially gaseous state, and the lower coil portion below the divider plate 120 contains working fluid in a substantially liquid state. The use of a divider plate 120 increases performance of the heat exchanger devices and systems of the present disclosure by eliminating the restrictions between a condenser and evaporator used in conventional thermosiphons. The position of the divider plate 120 along the coil can vary. For example, the divider plate can be positioned such that upper coil portion and the lower portion are substantially equivalent in length. In other embodiments, the divider plate can be positioned such that upper coil portion and the lower portion are from about 1% to about 99% of the total length of the coil. For example, depending on the overall configuration of the heat exchanger devices and systems and/or the enclosure-of-interest, the divider plate 120 can positioned such that the upper coil portion is about 40% of the total length of the coil, while the lower coil portion is about 60% of the total length of the coil. Whatever the configuration, the divider plate 120 creates a substantially air-tight seal that separates the external and internal airflow paths.

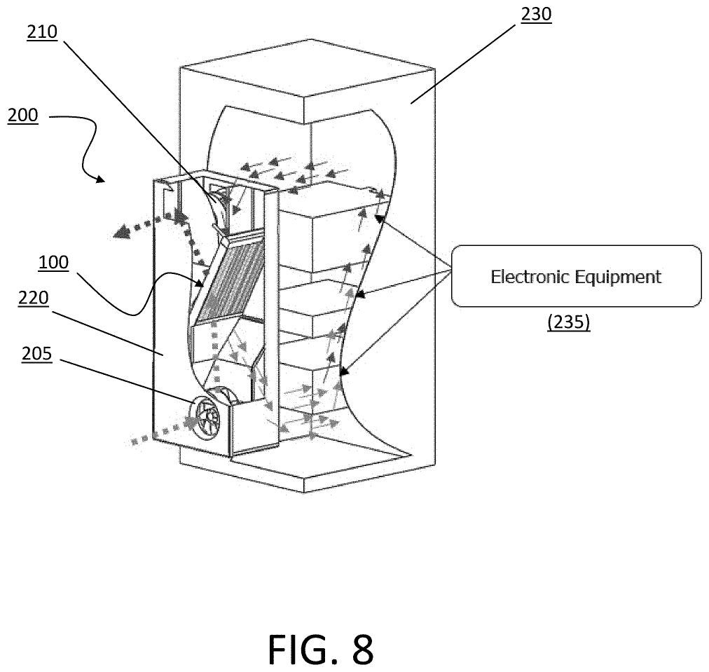

In some embodiments, the divider plate 120 can be welded, brazed, or fitted mechanically with a sealant compound into position during assembly of the heat exchanger device such that it is generally in a fixed position. Welding can include, for example, TIG welding or laser welding, though other suitable types of welding could also be used, as would be recognized by one of ordinary skill in the art based on the present disclosure. In other embodiments, the divider plate 120 is vertically adjustable along the length of the coil. For example, an adjustable divider plate 120 can be used to adapt to the heat load being generated in an enclosure-of-interest. Other system parameters that can be addressed using an adjustable divider plate 120, include, but are not limited to, external air temperature, internal air temperature, internal humidity, internal airflow, external humidity, time of day, day of year, external wind speed, external precipitation, static pressure of the working fluid, and functional capacity of the system. These and other parameters can be measured or assessed using one or more sensors designed to communicate with the adjustable divider plate 120, which can vary its vertical position along the coil based on the information from the one or more sensors. In this manner an adjustable divider plate can alter the configurations of the sealed compartment containing the internal fan and the sealed compartment containing the external fan (see, e.g., FIG. 8). In some embodiments, the adjustable divider plate is coupled to one or more portions of the sealed compartments containing the internal and external fans in order to ensure an air-tight seal as the divider plate changes position.

In addition to the channels 110 and microchannels 115, and the divider plate 120, embodiments of the single coil heat exchanger device of the present disclosure also include a header 130 and a footer 140 (FIG. 1B). The header 130 and footer 140 are positioned at the terminal ends of the coil and create sealed compartments in which the working fluid can pass from one channel to another to equalize pressure among the channels in the system (FIG. 2E). For example, as shown in FIGS. 2A-2E, the header 130 encloses the terminal ends of the channels 110 in the upper coil portion in a sealed compartment. The header 130 generally contains the working fluid in a substantially gaseous state, which forms condensate when exposed to cooler external air (FIG. 2F; see also FIG. 8). Similarly, the footer 140 encloses the terminal ends of the channels 110 in the lower coil portion in a sealed compartment. The footer 140 generally contains the working fluid in a substantially liquid state, which evaporates when exposed to warmer air from the internal environment of an enclosure-of-interest (FIG. 2F; see also FIG. 8). FIGS. 2C and 2D provide perspective views of the channels 110 extending into the header compartment at different depths. The exact depth by which the terminal ends of the channels 110 extend into the header 130 and footer 140 can vary depending on factors such as the number of channels, the type of working fluid, the size of the sealed compartment, and the like, as would be recognized by one of ordinary skill in the art based on the present disclosure.

Embodiments of the heat exchanger device 100 of the present disclosure can be sized and shaped in various ways that are suitable for a given purpose, location, and enclosure-of-interest. For example, as shown in FIG. 2A, the dimension “A” representing the depth of the channel 110 extending into the header 130 can be from 2 mm to 50 mm. In some embodiments, A is from 5 mm to 50 mm, 10 mm to 50 mm, 15 mm to 50 mm, 20 mm to 50 mm, 30 mm to 50 mm, or 40 mm to 50 mm. In some embodiments, A is 2 mm to 40 mm, 2 mm to 35 mm, 2 mm to 30 mm, 2 mm to 25 mm, 5 mm to 40 mm, 10 mm to 40 mm, 15 mm to 35 mm, or 20 mm to 30 mm. In some embodiments, A is 2 mm, 3 mm, 4 mm, 5 mm, 6 mm, 7 mm, 8 mm, 9 mm, 10 mm, 11 mm, 12 mm, 13 mm, 14 mm, 15 mm, 16 mm, 17 mm, 18 mm, 19 mm, 20 mm, 25 mm, 30 mm, 35 mm, 40 mm, 45 mm, or 50 mm. As would be recognized by one of ordinary skill in the art, the dimensions provided herein correspond to representative embodiments and are not intended to be limiting. That is, the dimensions of the devices described herein are scalable (increasing or decreasing), both independently and proportionally.

In some embodiments, as shown in FIG. 2A, the dimension “B” representing the depth of the header 130 can be from 20 mm to 100 mm. In some embodiments, B is from 30 mm to 100 mm, 40 mm to 100 mm, 50 mm to 100 mm, 60 mm to 100 mm, 70 mm to 100 mm, 80 mm to 100 mm, or 90 mm to 100 mm. In some embodiments, B is from 20 mm to 90 mm, 30 mm to 80 mm, 40 mm to 70 mm, or 50 mm to 60 mm. In some embodiments, B is 30 mm, 31 mm, 32 mm, 33 mm, 34 mm, 35 mm, 36 mm, 37 mm, 38 mm, 39 mm, 40 mm, 41 mm, 42 mm, 43 mm, 44 mm, 45 mm, 46 mm, 47 mm, 48 mm, 49 mm, or 50 mm.

In some embodiments, as shown in FIG. 2A, the dimension “C” representing the width of the channel 110 can be from 20 mm to 200 mm. In some embodiments, C is from 30 mm to 200 mm, 40 mm to 200 mm, 50 mm to 200 mm, 60 mm to 200 mm, 70 mm to 200 mm, 80 mm to 200 mm, or 90 mm to 200 mm. In some embodiments, C is from 20 mm to 190 mm, 30 mm to 180 mm, 40 mm to 170 mm, or 50 mm to 160 mm. In some embodiments, C is from 30 mm to 100 mm, 40 mm to 100 mm, 50 mm to 100 mm, 60 mm to 100 mm, 70 mm to 100 mm, 80 mm to 100 mm, or 90 mm to 100 mm. In some embodiments, C is from 20 mm to 90 mm, 30 mm to 80 mm, 40 mm to 70 mm, or 50 mm to 60 mm. In some embodiments, B is 30 mm, 31 mm, 32 mm, 33 mm, 34 mm, 35 mm, 36 mm, 37 mm, 38 mm, 39 mm, 40 mm, 41 mm, 42 mm, 43 mm, 44 mm, 45 mm, 46 mm, 47 mm, 48 mm, 49 mm, or 50 mm. As would be recognized by one of ordinary skill in the art, the dimensions provided herein correspond to representative embodiments and are not intended to be limiting. That is, the dimensions of the devices described herein are scalable (increasing or decreasing), both independently and proportionally.

Additionally, in some embodiments, the header 130 and footer 140 are symmetrically configured and/or are of uniform shape and size with respect to each other. In some embodiments, the header 130 and footer 140 are asymmetrically configured and/or are of variable shape and size with respect to each other. The shape of the header 130 and footer 140 can be rounded, oval, square, octagonal, and the like. In some embodiments, the header 130 and footer 140 are welded, brazed, or fitted mechanically with a sealant compound into position during assembly of the heat exchanger device such that they are generally in a fixed position. Welding can include, for example, TIG welding or laser welding, though other suitable types of welding could also be used, as would be recognized by one of ordinary skill in the art based on the present disclosure.

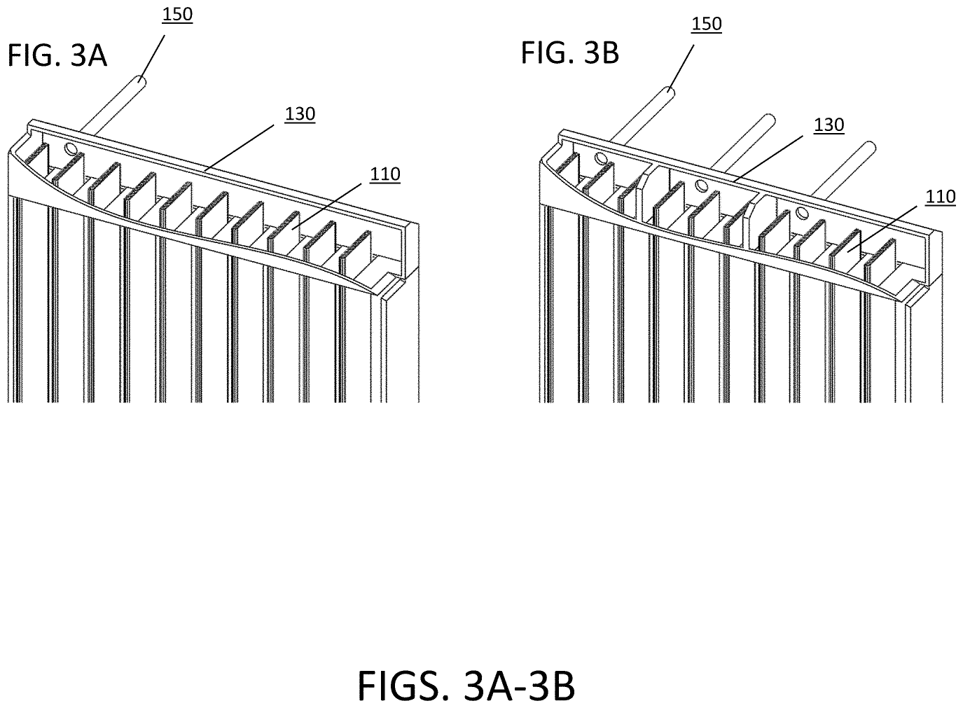

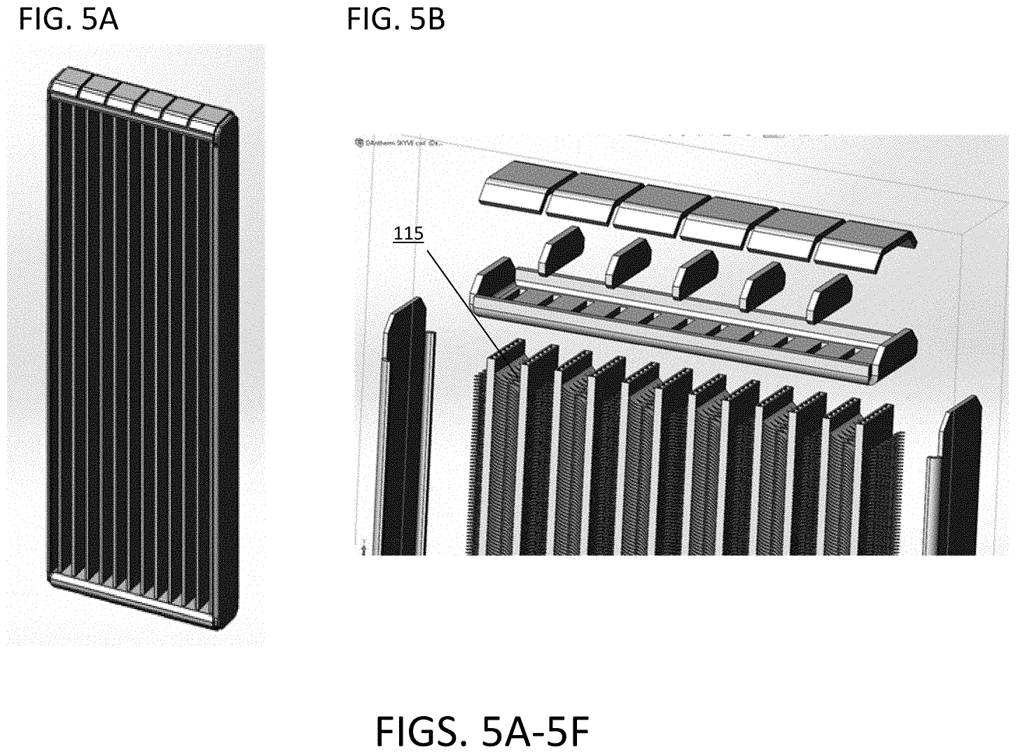

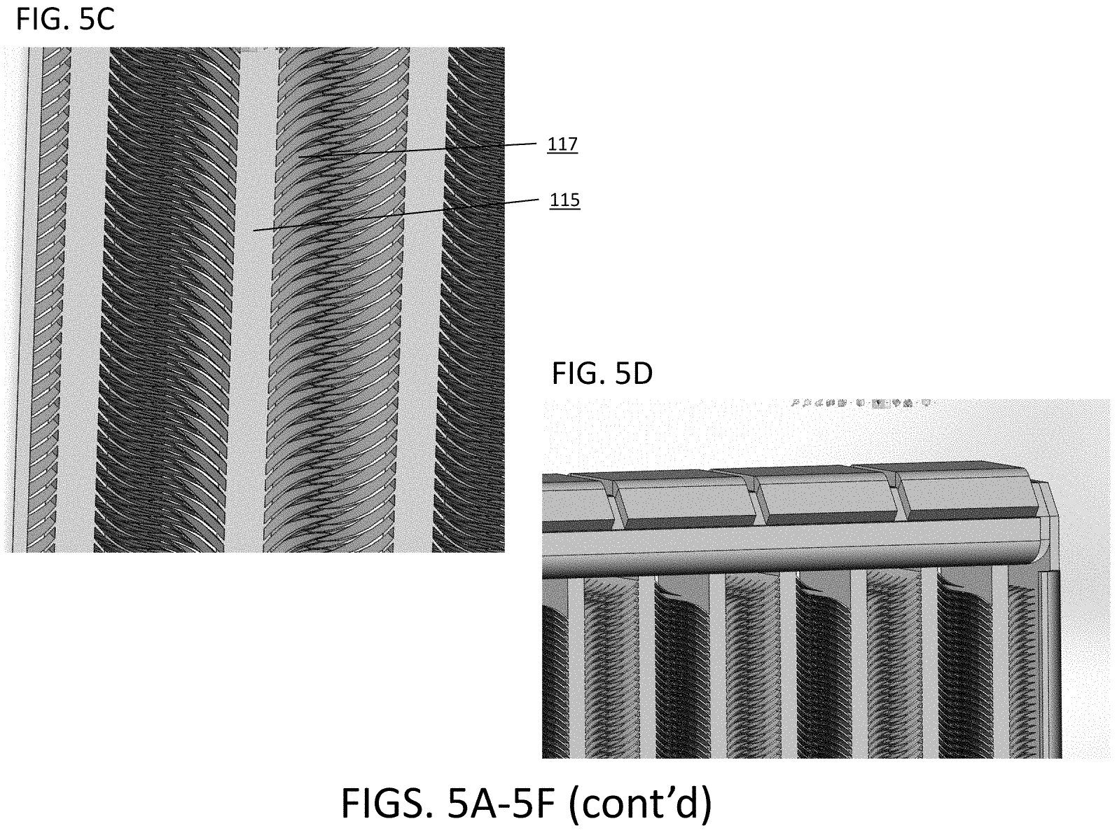

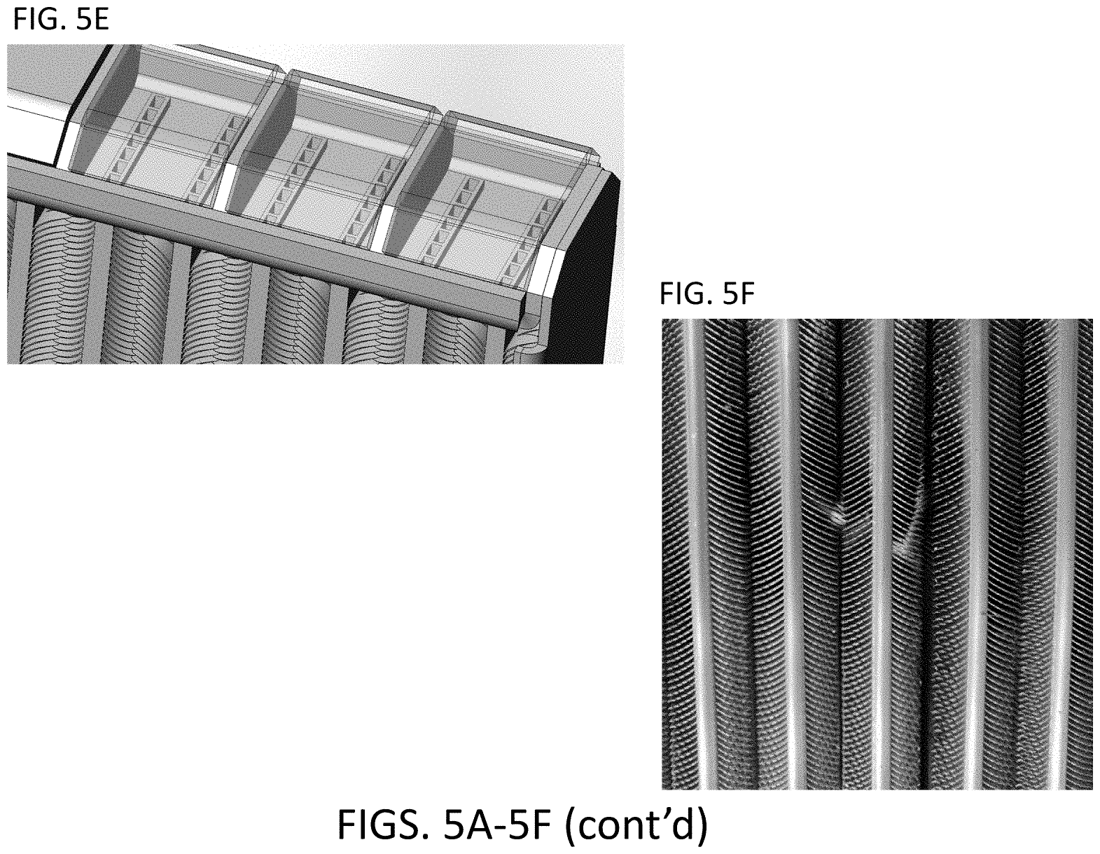

In some embodiments, the header 130 includes a charge port 150, as shown in FIGS. 2A-2E. The charge port 150 provides an inlet for injecting the working fluid into the coil. Generally, once the working fluid is injected into the coil and properly pressurized, the charge port 150 is permanently sealed off. In some embodiments, the single coil heat exchanger includes a single header compartment and charge port 150 (FIG. 3A). In other embodiments, the single coil heat exchanger includes multiple header and footer compartments, and multiple charge ports 150 (FIG. 3B), with various numbers of channels 110 extending into the header and footer compartments. The use of multiple charge ports 150 in conjunction with one or more dividers in the header and footer creates a plurality of coil circuits within a single coil assembly, with each header and footer compartment having at least one channel and at least one charge port (FIG. 3B; see also FIGS. 5A-5E). This configuration mitigates potential capacity/performance loss due to damage done to the coil (e.g., leaking working fluid, broken seal, etc.) by facilitating the disabling or removal of individual coil circuits. This helps prevent excessive capacity loss without having to replace the entire device or system.

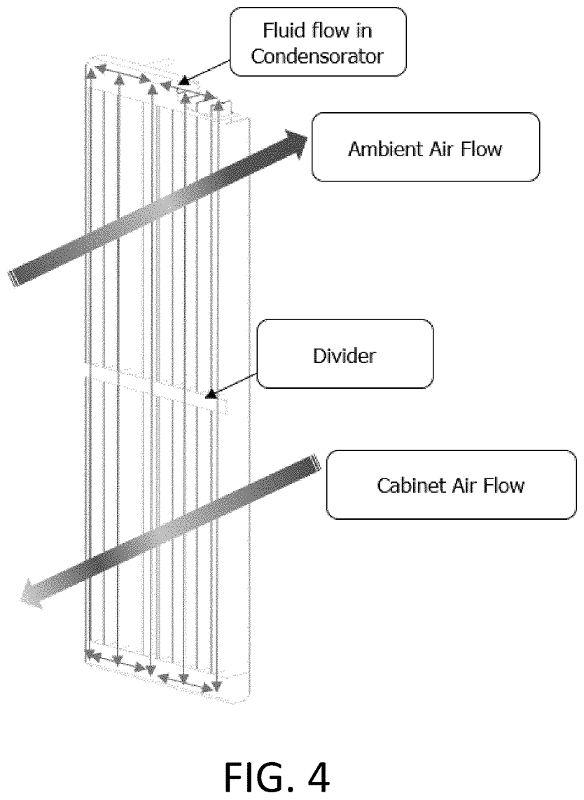

As referenced above, the upper coil portion above the divider plate 120, including the header 130, contains working fluid in a substantially gaseous state, while the lower coil portion below the divider plate 120, including the footer 140, contains working fluid in a substantially liquid state. As shown in FIG. 4, this general configuration of the single coil heat exchanger devices and systems of the present disclosure facilitates the flow of the working fluid (FIG. 4, small arrows), the internal airflow within the enclosure-of-interest circulating across the lower coil portion (FIG. 4, large arrow indicating cabinet airflow), and the external airflow from outside of the system flowing across the upper coil portion (FIG. 4, large arrow indicating ambient airflow) to prevent internal and external airflow contamination while removing heat from an enclosure-of-interest.

As used herein, the term “working fluid” generally refers to the fluid inside the channels/microchannels, header, and footer, and can be any fluid or gas capable of absorbing and/or transmitting energy. The working fluid is generally in a saturated state (i.e. liquid phase and vapor phase are in simultaneous equilibrium), and it undergoes a phase change due to gain or loss of heat. As the working fluid absorbs heat generated from inside an enclosure-of-interest, it is vaporized in the lower coil portion of the heat exchanger and rises upward in a gaseous state to the upper coil portion of the heat exchanger, where it is then exposed to cooler ambient air, which causes the working fluid to condense and fall back to the lower coil portion in a liquid state. This process results in the passive removal of heat from an enclosure-of-interest.

In some embodiments, the working fluid is an environmentally compatible refrigerant. In some embodiments, the working fluid is a dielectric, non-flammable fluid with low toxicity. In some embodiments, the working fluid is a type of hydrocarbon, such as, but not limited to, acetone, ethylene, isobutane, methanol, ethanol, tetrofluoroethane, hydrofluoroether, and/or combinations thereof. In some embodiments, the composition of the working fluid and internal pressure of the single coil heat exchanger system can be selected to provide a boiling point of the working fluid in the lower coil portion at about the desired operating temperature of the electronic devices in an enclosure-of-interest (e.g., approximately 30-100° C.). Examples of working fluid include, but are not limited to, Vextral XF (2,3-dihydrodeca-fluoropentane; DuPont), Flourinert Electronic Liquid FC-72 (3M), R134a (1,1,1,2-tetrofluoroethane; Honeywell), R1234yf (2,3,3,3-Tetrafluoroprop-1-ene; Honeywell), Novec 7100 (methoxy-nonafluorobutane; 3M), HFC245fa (1,1,1,3,3-Pentafluoropropane; Honeywell), R410a (mixture of difluoromethane (R-32) and pentafluoroethane (R-125); Honeywell), and various water/glycol mixtures.

Embodiments of the single coil heat exchanger devices and systems of the present disclosure also include a coil wherein the microchannels 115 are configured with a plurality of fins 117 extending from the microchannels 115 (FIGS. 5A-5F). The fins 117 can provide enhanced surface area for heat transfer. In accordance with these embodiments, the fins 117 can extend from one or both lateral sides of a microchannel 115 (FIGS. 5B-5F) and occupy the space between microchannels 117. The fins 117 can be bonded directly to the microchannels 115 through a process or welding or brazing, or the fins 117 can be constructed as part of an extrusion process. Additionally, as shown in FIG. 5F, fins can be orientated in the same direction, including an overlapping or non-overlapping orientation (or combinations thereof).

A single coil passive heat exchanger can include multiple header compartments and fins extending from the microchannels, as shown in FIGS. 5A-5F. FIG. 5A provides a perspective view (divider plate not shown) of the device, while FIG. 5B provides an exploded view. FIGS. 5C-5E provide magnified views of the plurality of microchannels within individual coil circuits and the fins extending from both lateral sides of the microchannels.

Embodiments of the present disclosure also include methods of manufacturing the single coil heat exchanger devices and systems of the present disclosure. In one embodiment, the heat exchanger device can be assemble using a brazing or welding process. Brazing can be performed by hand for smaller volumes or, for example, in a controlled atmospheric brazing oven for larger volumes. TIG welding can be performed by hand for smaller volumes, and laser welding is generally more suitable for larger volumes.

In some embodiments, the various internal and/or external surfaces of the components of the heat exchanger devices of the present disclosure can be coated. Coatings can extend the working life of these components and/or improve performance by reducing corrosion. Corrosion can take various forms, including but not limited to, galvanic, stress cracking, general, localized and caustic agent corrosion. Corrosion resistant coatings for various metals vary depending on the kind metal involved and the kind of corrosion prevention required. For example, to prevent galvanic corrosion in iron and steel alloys, coatings made from zinc and aluminum are useful. Larger components are often treated with zinc and aluminum corrosion resistant coatings because they provide reliable long-term corrosion prevention. Steel and iron fasteners, threaded fasteners, and bolts can be coated with a thin layer of cadmium, which helps block hydrogen absorption which can lead to stress cracking. In addition to cadmium, zinc, and aluminum coatings, nickel-chromium and cobalt-chromium can be used as corrosive coatings because of their low level of porosity. These coatings are extremely moisture resistant and therefore help inhibit the development of rust and the eventual deterioration of metal. Oxide ceramics and ceramic metal mixes are other examples of coatings that are strongly wear resistant, in addition to being corrosion resistant.

In some embodiments, the heat exchanger assembly (e.g., single coil comprising channels, the header, the footer, and the divider plate) is fitted together by hand or with simple tools. In some embodiments, the heat exchanger device, once assembled, can be inserted into a passive cooling system (e.g., system comprising the housing unit and fans) and rivetted or screwed into places. Gaskets and sealants can also be used to bond the assembled heat exchanger into the housing unit.

### 3. Systems

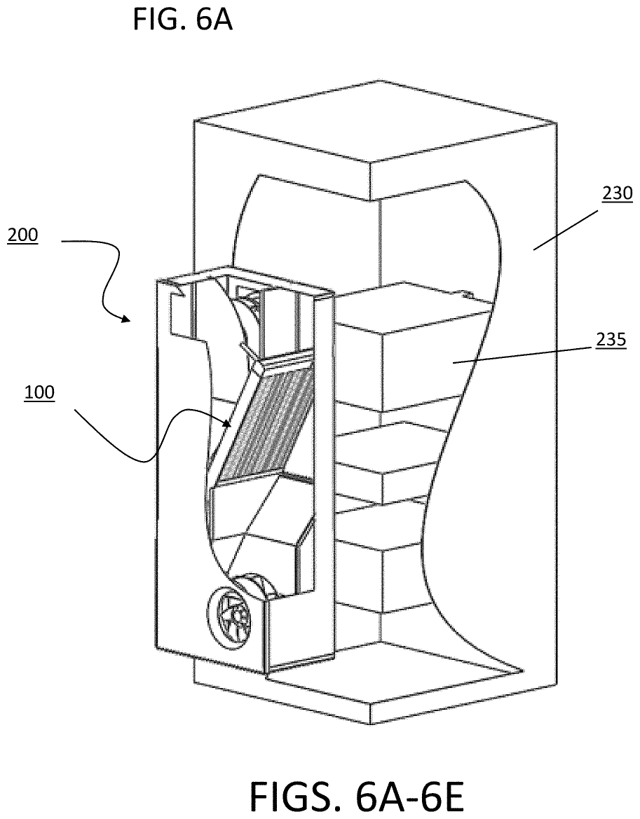

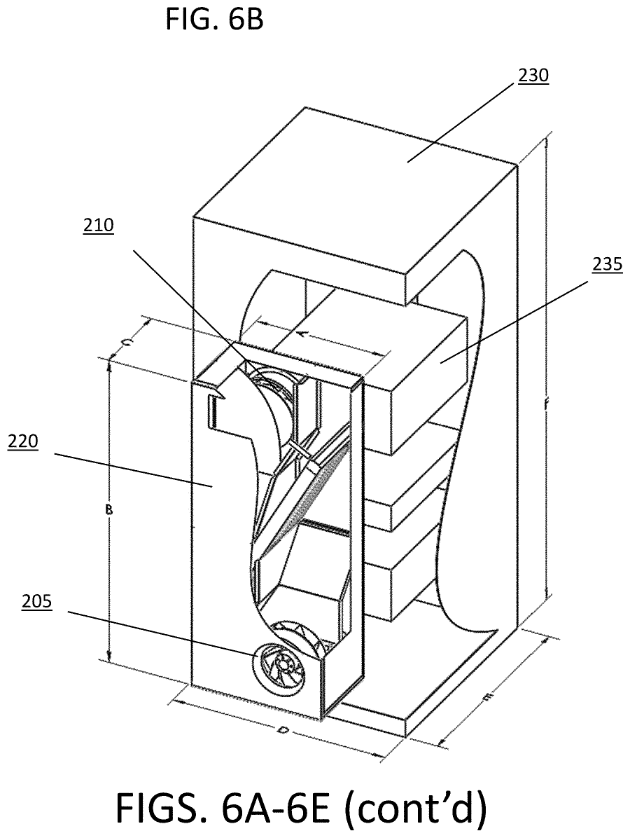

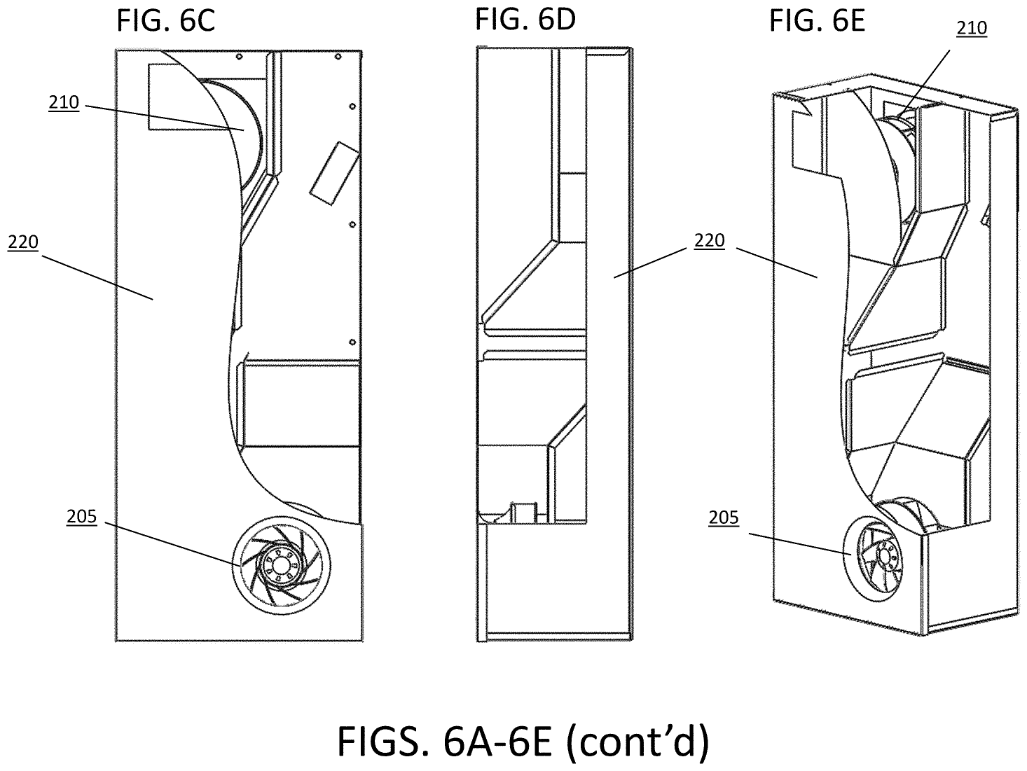

Embodiments of the present disclosure also include passive cooling systems comprising the single coil heat exchanger devices described above (“condensorator”). In accordance with these embodiments, the systems 200 can include any of the single coil passive heat exchanger devices 100 described herein, at least one fan 205/210, and a housing unit 220 that contains the heat exchanger device 100 and the at least one fan 205/210, as shown in FIGS. 6A and 6B. In some embodiments, the system includes an external fan 205 that brings in cool ambient air into the system, and an internal fan 210 that circulates air within an enclosure-of-interest (FIGS. 6A-6E). In some embodiments, the external fan 205 is positioned at the bottom portion of the heat exchanger device 100, and the internal fan 210 is positioned at the top portion of the heat exchanger device 100 (FIGS. 6A-6E). In other embodiments, the external fan 205 is positioned at the top portion of the heat exchanger device 100, and the internal fan 210 is positioned at the bottom portion of the heat exchanger device 100. In either embodiment, the external fan 205 is configured to circulate air from the external environment to the top portion of the heat exchanger device 100 (upper portion of the coil above the divider plate), and the internal fan 210 is configured to circulate air from the internal cabinet 230/235 to the bottom portion of the heat exchanger device 100 (lower portion of the coil below the divider plate).

In some embodiments, the heat exchanger device 100 is positioned at an angled configuration such that it is angled towards or away one side of the adjacent enclosure-of-interest (e.g., FIGS. 6A-6E). The system 200 is generally mounted to an enclosure-of-interest, such as but not limited to, an enclosure 230 (e.g., cabinet) that houses electrical or computer equipment 235, or a commercial or residential building. As would be recognized by one of ordinary skill in the art, the passive cooling systems of the present disclosure can work in conjunction with one or more active cooling technologies to reduce heat load for a given enclosure-of-interest.

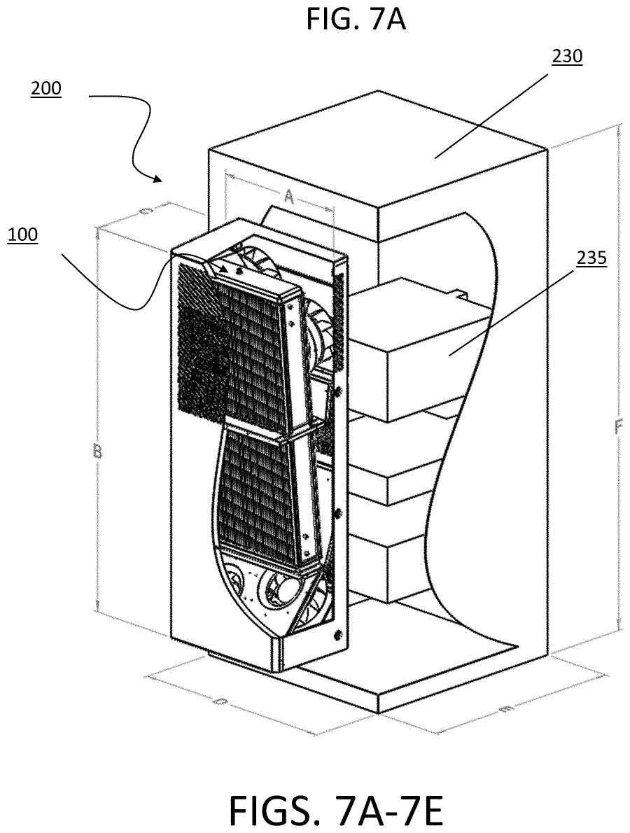

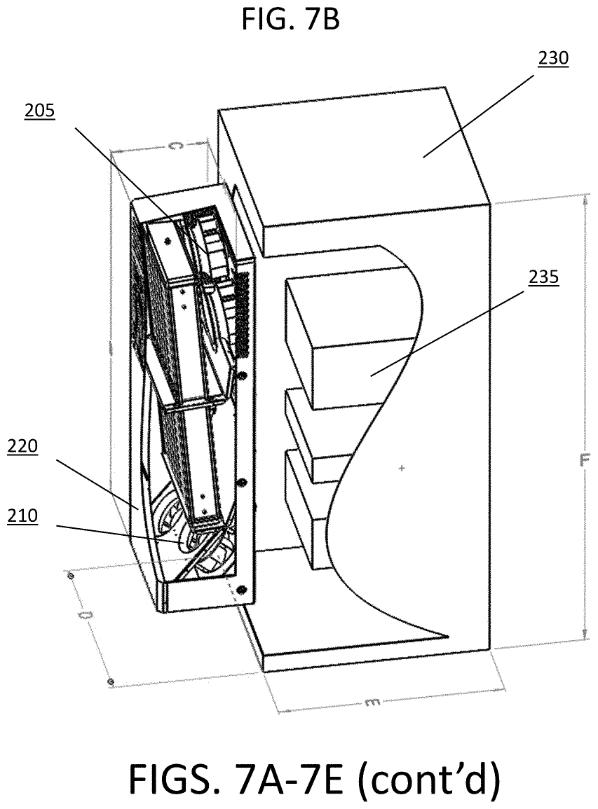

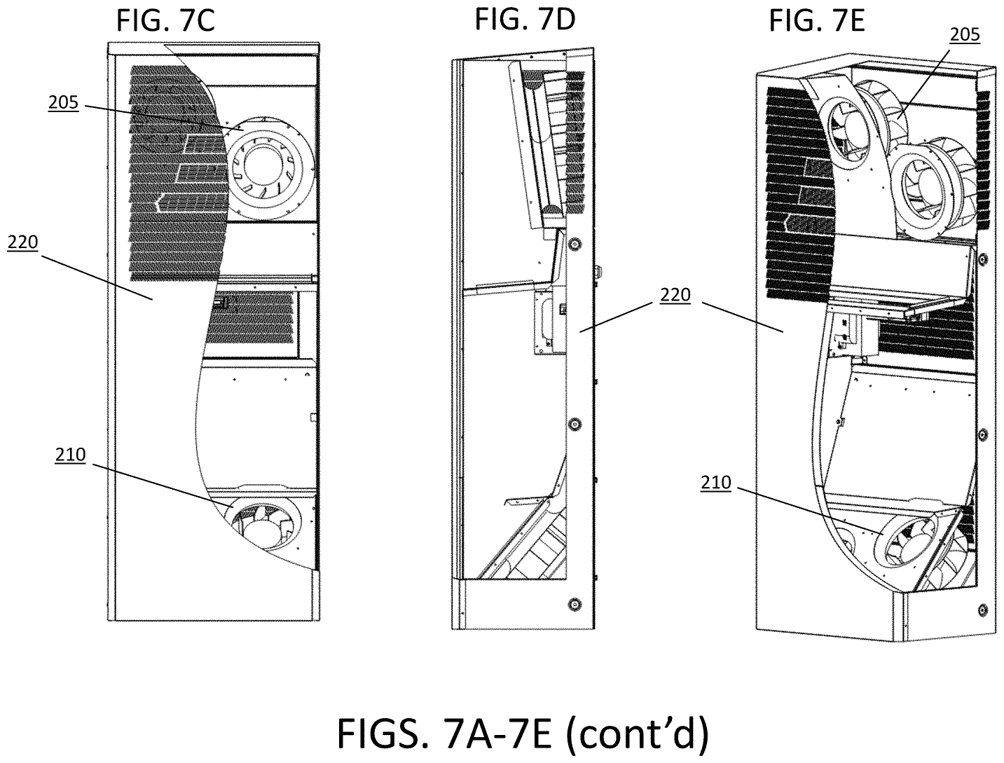

In some embodiments, the systems 200 can include any of the single coil passive heat exchanger devices 100 described herein, at least two fans 205/210, and a housing unit 220 that contains the heat exchanger device 100 and the at least two fans 205/210, as shown in FIGS. 7A and 7B. In some embodiments, the system includes two external fans 205 that bring in cool ambient air into the system, and two internal fans 210 that circulate air within an enclosure-of-interest (FIGS. 7A-7E). In some embodiments, the two internal fans 210 are positioned at the bottom portion of the heat exchanger device 100, and the two external fans 205 are positioned at the top portion of the heat exchanger device 100 (FIGS. 7A-7E). In other embodiments, the two external fans 205 are positioned at the bottom portion of the heat exchanger device 100, and the two internal fans 210 are positioned at the top portion of the heat exchanger device 100. In either embodiment, the external fans 205 are configured to circulate air from the external environment to the top portion of the heat exchanger device 100 (upper portion of the coil above the divider plate), and the internal fans 210 are configured to circulate air from the internal cabinet 230/235 to the bottom portion of the heat exchanger device 100 (lower portion of the coil below the divider plate).

In some embodiments, the heat exchanger device 100 is positioned at an angled configuration, such that it is angled towards or away from the adjacent enclosure-of-interest (e.g., FIGS. 7A-7E). The system 200 is generally mounted to an enclosure-of-interest, such as but not limited to, an enclosure 230 (e.g., cabinet) that houses electrical or computer equipment 235, or a commercial or residential building. As would be recognized by one of ordinary skill in the art, the passive cooling systems of the present disclosure can work in conjunction with one or more active cooling technologies to reduce heat load for a given enclosure-of-interest.

Embodiments of the heat exchanger system 200 of the present disclosure can be sized and shaped in various ways that are suitable for a given purpose and location. For example, as shown in FIG. 6B, the dimension “A” representing the width of the housing unit 220 can be from 100 mm to 1000 mm. In some embodiments, A is from 200 mm to 900 mm, from 300 mm to 800 mm, from 400 mm to 700 mm, or from 400 mm to 600 mm. In some embodiments, A is 400 mm, 410 mm, 420 mm, 430 mm, 440 mm, 450 mm, 460 mm, 470 mm, 480 mm, 490 mm, 500 mm, 510 mm, 520 mm, 530 mm, 540 mm, or 550 mm.

In some embodiments, as shown in FIG. 6B, the dimension “B” representing the height of the housing unit 220 can be from 500 mm to 2000 mm. In some embodiments, B is 750 mm to 1750 mm, from 850 mm to 1650 mm, from 950 mm to 1550 mm, from 1050 mm to 1450 mm, or from 1150 mm to 1350 mm. In some embodiments, B is 1000 mm, 1010 mm, 1020 mm, 1030 mm, 1040 mm, 1050 mm, 1060 mm, 1070 mm, 1080 mm, 1090 mm, 1100 mm, 1110 mm, 1120 mm, 1130 mm, 1140 mm, 1150 mm, 1160 mm, 1170 mm, 1180 mm, 1190 mm, 1200 mm, 1210 mm, 1220 mm, 1230 mm, 1240 mm, or 1250 mm.

In some embodiments, as shown in FIG. 6B, the dimension “C” representing the depth of the housing unit 220 can be from 100 mm to 1000 mm. In some embodiments, C is from 200 mm to 900 mm, from 250 mm to 800 mm, from 300 mm to 700 mm, or from 350 mm to 600 mm. In some embodiments, C is 200 mm, 210 mm, 220 mm, 230 mm, 240 mm, 250 mm, 260 mm, 270 mm, 280 mm, 290 mm, 300 mm, 310 mm, 320 mm, 330 mm, 340 mm, 350 mm, 360 mm, 370 mm, 380 mm, 390 mm, or 400 mm.

In some embodiments, as shown in FIG. 6B, the dimension “D” representing the width of the enclosure 230 can be from 500 mm to 1000 mm. In some embodiments, D is from 600 mm to 900 mm, from 650 mm to 950 mm, from 700 mm to 900 mm, or from 750 mm to 850 mm. In some embodiments, D is 700 mm, 710 mm, 720 mm, 730 mm, 740 mm, 750 mm, 760 mm, 770 mm, 780 mm, 790 mm, 800 mm, 810 mm, 820 mm, 830 mm, 840 mm, 850 mm, 860 mm, 870 mm, 880 mm, 890 mm, or 900 mm.

In some embodiments, as shown in FIG. 6B, the dimension “E” representing the depth of the enclosure 230 can be from 500 mm to 1000 mm. In some embodiments, E is from 600 mm to 900 mm, from 650 mm to 950 mm, from 700 mm to 900 mm, or from 750 mm to 850 mm. In some embodiments, E is 700 mm, 710 mm, 720 mm, 730 mm, 740 mm, 750 mm, 760 mm, 770 mm, 780 mm, 790 mm, 800 mm, 810 mm, 820 mm, 830 mm, 840 mm, 850 mm, 860 mm, 870 mm, 880 mm, 890 mm, or 900 mm.

In some embodiments, as shown in FIG. 6B, the dimension “F” representing the width of the enclosure 230 can be from 1500 mm to 3000 mm. In some embodiments, F is from 1750 mm to 2750 mm, from 2000 mm to 2500 mm, or from 2150 mm to 2400 mm. In some embodiments, F is 1700 mm, 1710 mm, 1720 mm, 1730 mm, 1740 mm, 1750 mm, 1760 mm, 1770 mm, 1780 mm, 1790 mm, 1800 mm, 1810 mm, 1820 mm, 1830 mm, 1840 mm, 1850 mm, 1860 mm, 1870 mm, 1880 mm, 1890 mm, or 1900 mm.

In some embodiments, the heat exchanger device 100 within the system 200 is positioned at an angle with reference to the ground. In some embodiments, the heat exchanger 100 is at any angle from 1 degree to 90 degrees with reference to the ground. In some embodiments, the heat exchanger 100 is at a 5 degree angle, a 10 degree angle, a 15 degree angle, a 20 degree angle, a 25 degree angle, a 30 degree angle, a 35 degree angle, a 40 degree angle, a 45 degree angle, a 50 degree angle, a 55 degree angle, a 60 degree angle, a 65 degree angle, a 70 degree angle, a 75 degree angle, an 80 degree angle, or an 85 degree angle. In some embodiments, the heat exchanger device 100 is positioned at an angled configuration such that it is angled towards or away from the adjacent enclosure-of-interest (e.g., FIGS. 7A-7E). In some embodiments, the heat exchanger device 100 is positioned at an angled configuration such that it is angled towards or away one side of the adjacent enclosure-of-interest (e.g., FIGS. 6A-6E).

As would be recognized by one of ordinary skill in the art, the dimensions of the systems provided above correspond to representative embodiments of the systems and devices and are not intended to be limiting. That is, the dimensions of the systems and devices described herein are scalable (increasing or decreasing), both independently and proportionally.

In some embodiments, the external fan 205 of the system 200 is positioned at the bottom portion of the housing unit 220 in a sealed compartment, while the internal fan 210 is positioned at the top portion of the housing unit 220 in a sealed compartment (FIGS. 6A and 6B). The external fan 205 draws external air into the sealed compartment and upward towards the upper coil comprising working fluid in a substantially gaseous state sufficient to cause condensation of the gaseous working fluid. Simultaneously, the internal fan 210 draws internal air from an enclosure-of-interest into the sealed compartment and downward towards the lower coil comprising working fluid in a substantially liquid state sufficient to cause evaporation of the liquid working fluid. In some embodiments, at least a portion of the sealed compartments are coupled to the divider plate 120 in order to prevent contamination of the internal and external airflow paths as the fans circulate the air. The housing unit 220 can also include a vent in the top portion of the system, opposite the internal fan 210, to allow the ambient air to circulate through the system (FIG. 8).

As one of ordinary skill in the art would recognize based on the present disclosure, FIG. 8 is a representation of the airflow that takes place in the embodiment depicted in FIGS. 6A-6E; however, the airflow that takes place in the embodiment depicted in FIGS. 7A-7E would be altered due to the alternate positioning of the external and internal fans, as described above.

In some embodiments, and as described above, the divider plate 120 can be brazed or welded into position during assembly of the heat exchanger device such that it is generally in a fixed position. In other embodiments, the divider plate 120 is vertically adjustable along the length of the coil. For example, an adjustable divider plate 120 can be used to adapt to the heat load being generated in an enclosure-of-interest. Other system parameters that can be addressed using an adjustable divider plate 120, include, but are not limited to, external air temperature, internal air temperature, internal humidity, external humidity, time of day, day of year, external wind speed, external precipitation, static pressure of the working fluid, and functional capacity of the system. Additionally, the heat exchanger devices of the present disclosure can include a single divider or multiple dividers to demarcate the evaporator portion from the condenser portion. Multiple dividers may be suitable when adjusting one or more of the system parameters described above.

These and other parameters can be measured or assessed using one or more sensors designed to communicate with the adjustable divider plate 120, which can vary its vertical position along the coil based on the information from the one or more sensors. In this manner an adjustable divider plate can alter the configurations of the sealed compartment containing the internal fan and the sealed compartment containing the external fan (see, e.g., FIG. 8). In some embodiments, the adjustable divider plate is coupled to one or more portions of the sealed compartments containing the internal and external fans in order to ensure an air-tight seal as the divider plate changes position.

Embodiments of the heat exchanger systems of the present disclosure also include coupling multiple heat exchanger devices 100 within a system 200, and/or multiple heat exchanger systems 200 in series or in parallel to function as a coordinated unit. In accordance with these embodiments, system parameters such as fan speed and divider plate position can be adjusted in one or more of the heat exchanger devices/systems to maximize cooling capacity and/or performance and system efficiency. In some embodiments, the system further comprises a master and two or more slaves, and a computer processor configured to control power delivery from the heat exchanger system 200 to the fans and/or divider plates. In some embodiments, each heat exchanger device 100 in a system of multiple devices or systems is individually controlled by one of the slaves.

### 4. Command/Control

Certain steps, operations, or processes described herein (e.g., for modulating fan speed or divider plate location) may be performed or implemented with one or more hardware or software modules, alone or in combination with other devices. In one embodiment, a software module is implemented with a computer program product comprising a computer-readable medium containing computer program code, which can be executed by a computer processor for performing any or all of the steps, operations, or processes described.

Embodiments of the invention may also relate to an apparatus for performing the operations herein (e.g., modulating fan speed or divider plate location). This apparatus may be specially constructed for the required purposes, and/or it may comprise a general-purpose computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments of the invention may also relate to a product that is produced by a computing process described herein. Such a product may comprise information resulting from a computing process, where the information is stored on a non-transitory, tangible computer readable storage medium and may include any embodiment of a computer program product or other data combination described herein.

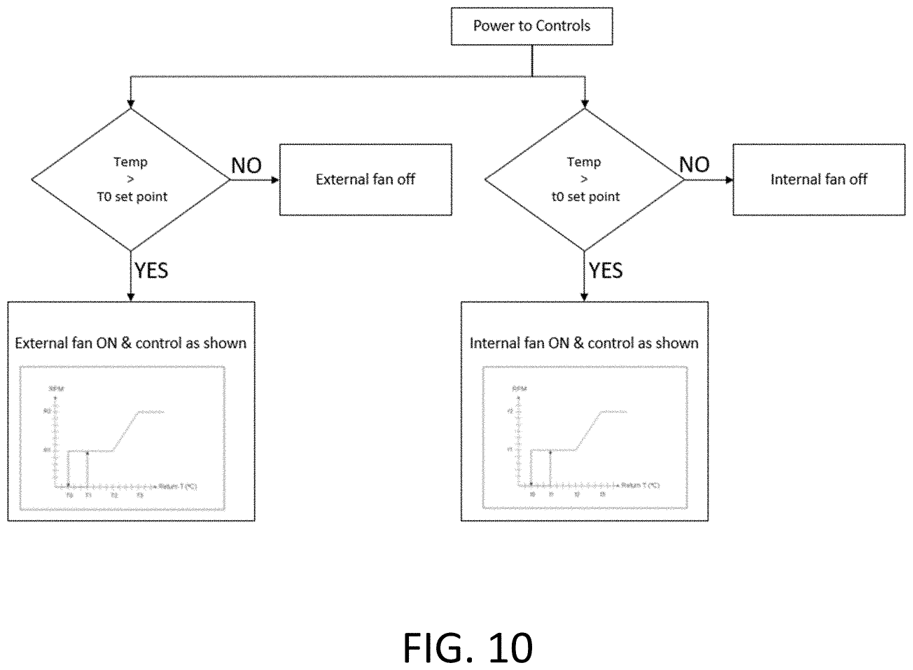

In one embodiment, as shown in the representative flowchart in FIG. 10, command/control operational processes for the single coil passive heat exchanger devices/systems of the present disclosure can include commands for operating both the internal and external fans in response to various system parameters. For example, commands can be executed to send power to the controls of the system, such as when the internal and/or external temperature is more than or less than a temperature set point or threshold. If the temperature does not reach a predetermined set point, power to the internal or external fan can be removed (“NO”). Alternatively, if the temperature reaches a predetermined set point, power to the external and/or internal fan can be provided (“YES”), and can also be controlled based on, for example, continual temperature measurements. In some embodiments, this exemplary command/control process can be implemented for other components of the devices and systems of the present disclosure (e.g., for modulation of the divider plate), and based on other system parameters in addition to temperature.

### 5. Examples and Methods of Use

As described herein, embodiments of the single coil heat exchanger devices and systems of the present disclosure can be mounted to any enclosure-of-interest to reduce heat load generated within the enclosure-of-interest (e.g., heat load generated by computer or electrical equipment, batteries, drives, relays, switches, transformers, electrical, computer, or any combinations thereof). In accordance with these embodiments, the devices and systems of the present disclosure can provide enhanced or improved cooling capacity and/or performance for a given enclosure without contaminating internal and external airflow paths. As shown in Table 1 (below), the single coil heat exchanger passive cooling systems of the present disclosure demonstrated significant improvements in capacity (W/F, or watts per ° F.) with the same air flow (1000 CFM) but with less overall size, cost, and working fluid.

TABLE 1

| | Two-Coil | | Single Coil Design | |
|---|---|---|---|---|
| | Thermosiphon Design | | (“Condensorator”) | |
| | (e.g., TF110) | | (e.g., TF200) | |
| Number of Coils | 2 sets of 2 | | 1 | |
| Refrigerant | 2 × 700 | g | 500 | g |
| Face Area (evap) | 20″h × 18″w | | 19″h × 19″w | |
| Face Area (cond) | 20″h × 18″w | | 19″h × 19″w | |
| Airflow | 1000 CFM (1700 m³/hr) | | 1000 CFM (1700 m³/hr) | |
| Capacity | 120 | W/F | 215 | W/F |

| | | |
|---|---|---|
| $/W/F | $$$ | $$ |

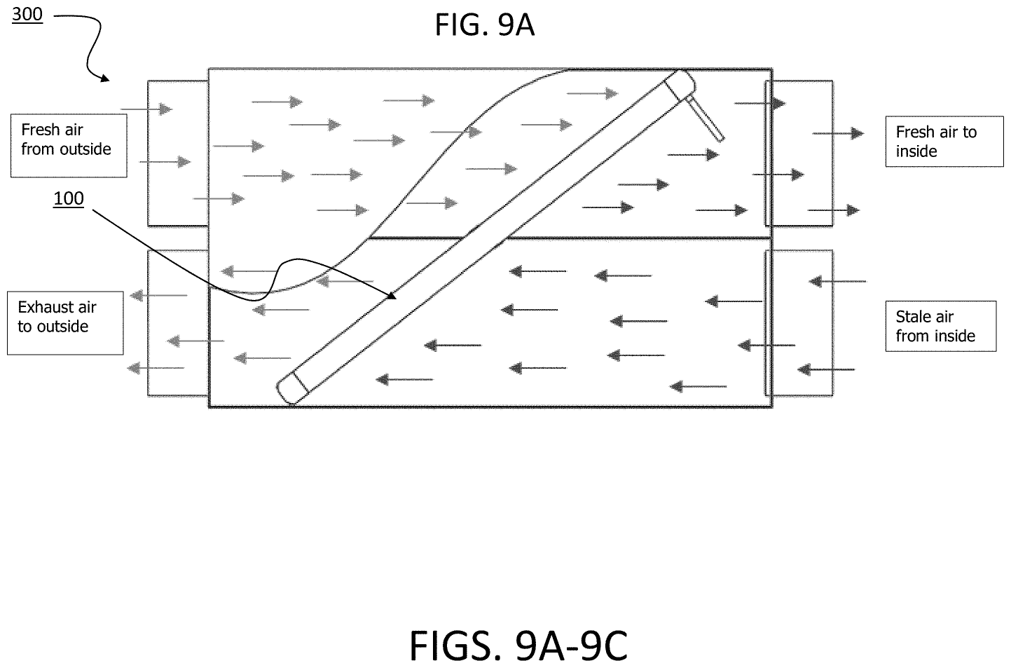

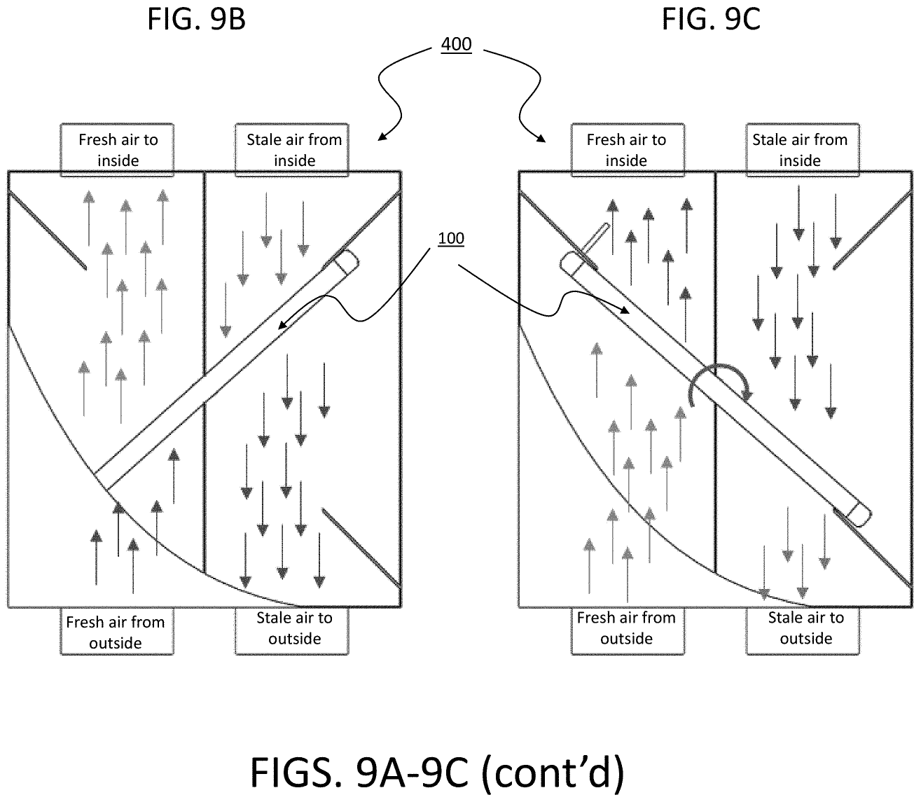

In some embodiments, the single coil heat exchanger passive cooling systems of the present disclosure can be mounted to a commercial or residential building to provide passive cooling of these enclosures (e.g., integrated into an air exchange unit). For example, as shown in FIG. 9A, the system 300 can be positioned more horizontally, as compared to system 200 described above. Referring to FIG. 9A, the arrows at the top and to the left of the heat exchanger (flowing left to right) represent cooler ambient airflow moving across the upper coil portion (e.g., condenser), while the arrows at the bottom and to the right of the heat exchanger (flowing right to left) represent warmer airflow from the enclosure moving across the lower coil portion (e.g., evaporator). In this configuration, and as described further herein, the single coil heat exchanger devices of the present disclosure provide enhanced cooling of one or more enclosures in a residential or commercial building, while preventing contamination of the internal environment with dust, debris, dirt, salt, precipitation, and the like, from the outside environment.

In one embodiment, system 300 can be about 18″×12″×14″ in size, and provide approximately 50-500 CFM for an approximately 4,000 ft² enclosure. This is about 4,500 CFM/hr of airflow. Other configurations of the system 300 can also be constructed based on various factors, such as system parameters, the working fluid used, the size and spatial limitations of the enclosure-of-interest, the heat load of the enclosure-of-interest, the external environment, and the like, as would be recognized by one of ordinary skill in the art based on the present disclosure.

One limitation of currently available passive cooling systems is the ability to transfer heat in reverse. FIGS. 9B and 9C include representative schematics of a system 400 comprising the single coil passive heat exchanger of the present disclosure integrated into the ductwork of a residential or commercial building, which includes dampers to reverse the direction of airflow. For example, as the ambient temperature climbs, the system 400 transfers heat from the ambient to the exhaust, leaving only cool fresh air to enter inside. This can be facilitated, for example, through the use of dampers in the ductwork of the residential building. In other embodiments, this can be addressed by making the system 400 part of the damper. For example, as the damper shifts position, the fresh air is heated or cooled as necessary. In one embodiment, the system 400 has approximate dimensions of 40″×36″×12″. In another embodiment, the system 400 includes a smaller heat exchanger device 100, and has approximate dimensions of dimensions to 30″×27″×12.″

It will be readily apparent to those skilled in the art that other suitable modifications to the devices and systems of the present disclosure are feasible, including, for example, scalability of the system. It is also understood that the foregoing detailed description and accompanying examples are merely illustrative and are not to be taken as limitations upon the scope of the disclosure, which is defined solely by the appended claims and their equivalents. Various changes and modifications to the disclosed embodiments will be apparent to those skilled in the art. Such changes and modifications, including without limitation those relating to the dimensions, materials, configurations, and/or methods of use of the devices and systems of the present disclosure, may be made without departing from the spirit and scope thereof.

1-40. (canceled)

41. A single coil passive heat exchanger device.

42. The device of claim 41, wherein the coil comprises a plurality of channels.

43. The device of claim 41, wherein the coil comprises a working fluid in a saturated state.

44. The device of claim 41, wherein the coil is comprised of aluminum or an aluminum alloy.

45. The device of claim 41, wherein the device further comprises a divider plate.

46. The device of claim 45, wherein the divider plate creates a substantially air-tight seal that divides the coil into an upper coil portion and a lower coil portion.

47. The device of claim 46, wherein the upper coil comprises working fluid in a substantially gaseous state, and wherein the lower coil comprises working fluid in a substantially liquid state.

48. The device of claim 46, wherein the divider plate is positioned such that the upper and lower coil portions are substantially equivalent in length.

49. The device of claim 46, wherein the divider plate is positioned such that the upper and lower coil portions are from about 1% to about 99% of the total length of the coil.

50. The device of claim 45, wherein the divider plate is welded, brazed or fitted mechanically with a sealant compound into a stationary position.

51. The device of claim 45, wherein the divider plate is vertically adjustable along the length of the coil.

52. The device of claim 41, wherein the device further comprises a header and a footer positioned at each terminal end of the coil.

53. The device of claim 52, wherein the header and footer are sealed at each terminal end of the coil to create sealed header and footer compartments, wherein the working fluid can move freely within both the header and footer compartments and within the plurality of channels.

54. The device of claim 52, wherein the header comprises working fluid in a substantially gaseous state, and wherein the footer comprises working fluid in a substantially liquid state.

55. The device of claim 52, wherein the header further comprises a charge port through which working fluid is added to the device.

56. The device of claim 52, wherein the header and footer are divided into a plurality of sealed header and footer compartments that create a plurality of coil circuits, with each header and footer compartment comprising at least one channel and at least one charge port.

57. The device of claim 42, wherein the plurality of channels each comprise a plurality of microchannels.

58. The device of claim 57, wherein the plurality of microchannels each comprise a plurality of fins extending from the plurality of microchannels that increase the surface area for heat transfer.

59. The device of claim 57, wherein the plurality of fins extends from one or both lateral sides of a microchannel.

60. The device of claim 57, wherein the plurality of fins is bonded to the plurality of microchannels.

61. The device of claim 57, wherein the plurality of fins is formed from the same material as that of the plurality of microchannels.

62. A passive cooling system comprising:
the single coil passive heat exchanger device of claim 41;
at least one fan; and
a housing unit.

63. The system of claim 62, wherein the system comprises one or more external fan(s) and one or more internal fan(s).

64. The system of claim 63, wherein the one or more external fan(s) are positioned in the bottom portion of the housing unit in a sealed compartment coupled to the divider plate.

65. The system of claim 64, wherein the one or more external fan(s) draw external air into the sealed compartment and upward towards the upper coil comprising working fluid in a substantially gaseous state sufficient to cause condensation of the gaseous working fluid.

66. The system of claim 63, wherein the one or more internal fan(s) are positioned in the top portion of the housing unit in a sealed compartment coupled to the divider plate.

67. The system of claim 66, wherein the one or more internal fan(s) draw internal air from an enclosure-of-interest into the sealed compartment and downward towards the lower coil comprising working fluid in a substantially liquid state sufficient to cause evaporation of the liquid working fluid.

68. The system of claim 63, wherein the one or more external fan(s) are positioned in the top portion of the housing unit in a sealed compartment coupled to the divider plate.

69. The system of claim 68, wherein the one or more external fan(s) draw external air into the sealed compartment and against the upper coil comprising working fluid in a substantially gaseous state sufficient to cause condensation of the gaseous working fluid.

70. The system of claim 63, wherein the one or more internal fan(s) are positioned in the bottom portion of the housing unit in a sealed compartment coupled to the divider plate.

71. The system of claim 70, wherein the one or more internal fan(s) draw internal air from an enclosure-of-interest into the sealed compartment and against the lower coil comprising working fluid in a substantially liquid state sufficient to cause evaporation of the liquid working fluid.

72. The system of claim 62, wherein the angle of the coil is from 1 to 90 degrees with reference to the ground.

73. The system of claim 62, wherein the system is mounted to an enclosure-of-interest, and wherein the enclosure-of-interest houses one or more of batteries, drives, relays, switches, transformers, electrical, computer, or any combinations thereof, which generate thermal load.

74. The system of claim 62, wherein the system is mounted to an enclosure-of-interest, and wherein the enclosure-of-interest is a commercial or residential building.

75. The system of claim 62, wherein the speed of the one or more external fan(s) and one or more internal fan(s) are adjustable based on one or more system parameters.

76. The system of claim 75, wherein the one or more system parameters comprise at least one of external air temperature, internal air temperature, internal humidity, internal airflow, external humidity, time of day, day of year, external wind speed, external precipitation, static pressure of the working fluid, and functional capacity of the system.

77. The system of claim 75, wherein the one or more system parameters are measured using at least one sensor.

78. The system of claim 77, wherein data provided by the at least one sensor is transferable to a computing device that can be read by a user.

79. The system of claim 62, wherein the divider plate is vertically adjustable along the length of the coil, and wherein adjusting the position of the divider plate on the coil alters the configurations of the sealed compartment containing the one or more internal fan(s) and the sealed compartment containing the one or more external fan(s).

80. The system of claim 79, wherein the position of the divider plate is adjustable based on information from the one or more system parameters read by the at least one sensor.
